(19) United States
(12) Patent Application Publication
(10) Pub. No.: US 2025/0060402 A1
(43) Pub. Date: Feb. 20, 2025

(54) SYSTEMS AND METHODS FOR PERFORMING QUALITY CONTROL

(71) Applicant: Amphenol AssembleTech (Xiamen) Co., Ltd., Xiamen (CN)

(72) Inventors: Jesus Jaramillo, Rosenberg, TX (US); David Ferroil Rosenboom, Port O'Connor, TX (US)

(73) Assignee: Amphenol AssembleTech (Xiamen) Co., Ltd., Xiamen (CN)

(21) Appl. No.: 18/799,773

(22) Filed: Aug. 9, 2024

Related U.S. Application Data
(60) Provisional application No. 63/520,474, filed on Aug. 18, 2023.

(51) Int. Cl. G01R 31/11; G01R 27/16

(52) U.S. Cl. CPC G01R 31/11; G01R 27/16

(57) ABSTRACT

Techniques for performing quality control in the manufacture of electrical components are provided. The techniques include obtaining electrical characterization data from the electrical components by using test equipment to measure electrical responses of the electrical components and processing, using at least one processor, the electrical characterization data to determine quantile statistics for the electrical characterization data. The techniques additionally include generating, using the at least one processor, a graphical user interface containing a visualization of the determined quantile statistics and displaying, using a display device, the generated graphical user interface.

### CROSS-REFERENCE TO RELATED APPLICATIONS

This application claims the benefit under 35 U.S.C. § 119(e) of U.S. Provisional Patent Application No. 63/520,474, filed Aug. 18, 2023, and titled “Systems and Methods for Performing Quality Control,” which is incorporated by reference herein in its entirety.

### BACKGROUND

Quality control is a process by which a business works to maintain and/or improve product or service quality. Historically, quality control was implemented in conjunction with the rise in mass production and could be performed by, for example, comparing a finished product to a drawing of the product. Modern quality control may be implemented using tolerance limits or controls on acceptable quality levels.

### SUMMARY

Some embodiments provide for a method of performing quality control in manufacture of a plurality of electrical components. The method comprises: obtaining electrical characterization data by using test equipment to measure electrical responses of the plurality of electrical components; processing, using at least one processor, the electrical characterization data to determine quantile statistics for the electrical characterization data; generating, using the at least one processor, a graphical user interface containing a visualization of the determined quantile statistics; and displaying, using a display device, the generated graphical user interface.

Some embodiments provide for a system for performing quality control in manufacture of a plurality of electrical components. The system comprises: test equipment configured to measure electrical responses of the plurality of electrical components; a display device; and at least one processor. The at least one processor is configured to perform: obtaining electrical characterization data by causing the test equipment to measure electrical responses of the plurality of electrical components; processing the electrical characterization data to determine quantile statistics for the electrical characterization data; generating a graphical user interface containing a visualization of the determined quantile statistics; and causing the display device to display the generated graphical user interface.

In some embodiments, the techniques further comprise identifying a quality control action to perform based on information in the graphical user interface containing the visualization of the determined quantile statistics.

In some embodiments, the techniques further comprise performing the identified quality control action.

In some embodiments, identifying the quality control action comprises identifying a maintenance action to perform maintenance on a tool used in the manufacture of the plurality of electrical components.

In some embodiments, identifying the quality control action comprises identifying a selection of a production process to manufacture the plurality of electrical components.

In some embodiments, identifying the quality control action comprises identifying a maintenance action to perform maintenance on the test equipment.

In some embodiments, identifying the quality control action comprises identifying a selection of a supplier of a part used in manufacturing the plurality of electrical components.

In some embodiments, identifying the quality control action comprises identifying feedback to provide to a supplier of a part used in manufacturing the plurality of electrical components.

In some embodiments, measuring an electrical response of an electrical component of the plurality of electrical components comprises: generating, using the test equipment, an electrical stimulus signal; providing the electrical stimulus signal as input to the electrical component; and measuring, using the test equipment, a reflected or transmitted signal output by the electrical component.

In some embodiments, measuring an electrical response of an electrical component of the plurality of electrical components comprises measuring an electrical response comprising a discrete function of a parameter, the discrete function comprising a set of data points comprising pairs of measured values and parameter values.

In some embodiments, the pairs of measured values and parameter values comprise pairs of measured signal amplitude values and time values, pairs of measured signal amplitude values and frequency values, and/or pairs of measured impedance values and time values.

In some embodiments, determining quantile statistics for the electrical characterization data includes calculating, for each parameter value of the measured electrical responses, a median of the measured values associated with a same parameter value.

In some embodiments, determining quantile statistics for the electrical characterization data includes calculating, for each parameter value of the measured electrical responses, a quartile of the measured values associated with a same parameter value.

In some embodiments, determining quantile statistics for the electrical characterization data includes calculating, for each parameter value of the measured electrical responses, a decile of the measured values associated with a same parameter value.

In some embodiments, generating the graphical user interface comprises generating a graph including one or more shaded regions or lines representative of the determined quantile statistics.

In some embodiments, determining quantile statistics for the electrical characterization data comprises determining median statistics; and generating the graph includes generating a line representative of the determined median statistics.

In some embodiments, generating the graph includes assigning a first color to illustrate a first shaded region representative of a first quantile and assigning a second color to illustrate a second shaded region representative of a second quantile, the first color being different than the second color.

In some embodiments, electrical components of the plurality of electrical components comprise cable assemblies including one or more differential pairs of conductors; and obtaining the electrical characterization data comprises measuring, using the test equipment, one of a selection of impedance, insertion loss, return loss, far end crosstalk, near end crosstalk, far end component contribution integrated crosstalk noise, near end component contribution integrated crosstalk noise, impedance mix-mode parameters, and/or skew of the cable assemblies.

In some embodiments, obtaining the electrical characterization data comprises measuring the impedance of the cable assemblies by performing time domain reflectometry.

In some embodiments, performing time domain reflectometry comprises: transmitting a differential electrical signal through a differential pair of conductors of the cable assemblies from a first side of the cable assemblies to a second side of the cable assemblies, the differential electrical signal comprising a step stimulus having a rise time equal to a data rate Nyquist frequency; and measuring, at the first side of the cable assemblies, a reflected electrical signal as a function of time.

In some embodiments, obtaining the electrical characterization data comprises measuring the insertion loss of the cable assemblies by: transmitting a differential electrical signal through a differential pair of conductors of the cable assemblies from a first side of the cable assemblies to a second side of the cable assemblies, the differential electrical signal having a frequency that is varied over time; and measuring, at the second side of the cable assemblies, a transmitted electrical signal as a function of frequency.

In some embodiments, obtaining the electrical characterization data comprises measuring return loss of the cable assemblies by: transmitting a differential electrical signal through a differential pair of conductors of the cable assemblies from a first side of the cable assemblies to a second side of the cable assemblies, the differential electrical signal having a frequency that is varied over time; and measuring, at the first side of the cable assemblies, a reflected electrical signal as a function of frequency.

In some embodiments, obtaining the electrical characterization data comprises measuring far end crosstalk of the cable assemblies by: transmitting a differential electrical signal through a first differential pair of conductors of the cable assemblies from a first side of the cable assemblies to a second side of the cable assemblies, the differential electrical signal having a frequency that is varied over time, and the first differential pair of conductors being adjacent a second differential pair of conductors; and measuring, at the second side of the cable assemblies and from the second differential pair of conductors, a transmitted electrical signal as a function of frequency.

In some embodiments, obtaining the electrical characterization data comprises measuring near end cross talk of the cable assemblies by: transmitting a differential electrical signal through a first differential pair of conductors of the cable assemblies from a first side of the cable assemblies to a second side of the cable assemblies, the differential electrical signal having a frequency that is varied over time, and the first differential pair of conductors being adjacent a second differential pair of conductors; and measuring, at the first side of the cable assemblies and from the second differential pair of conductors, a transmitted electrical signal as a function of frequency.

In some embodiments, obtaining the electrical characterization data comprises measuring mix-mode parameters of the cable assemblies by: transmitting a differential electrical signal through a differential pair of conductors of the cable assemblies from a first side of the cable assemblies to a second side of the cable assemblies, the differential electrical signal having a frequency that is varied over time; and measuring, at the second side of the cable assemblies, a transmitted common-mode electrical signal as a function of frequency.

In some embodiments, obtaining the electrical characterization data comprises measuring skew by performing intra-pair skew measurements as a function of time or as a function of frequency.

In some embodiments, obtaining the electrical characterization data comprises selecting a subset of the electrical characterization data based on serial numbers associated with the plurality of electrical components, a date of manufacture of the plurality of electrical components, lot numbers associated with the plurality of electrical components, and/or manufacturing shifts associated with a time of manufacture of the plurality of electrical components.

### BRIEF DESCRIPTION OF DRAWINGS

Various aspects and embodiments will be described with reference to the following figures. It should be appreciated that the figures are not drawn to scale. In the drawings, each identical or nearly identical component that is illustrated in various figures is represented by a like numeral. For purposes of clarity, not every component may be labeled in every drawing.

FIG. 1 is a schematic diagram of an electronic testing unit, in accordance with some embodiments of the technology described herein.

FIG. 2A illustrates a cable assembly, in accordance with some embodiments of the technology described herein.

FIG. 2B is a schematic circuit diagram illustrating the principles of differential signaling, in accordance with some embodiments of the technology described herein.

FIG. 3 is a schematic diagram illustrating the calculation of quartile ranges, in accordance with some embodiments of the technology described herein.

FIG. 4 is a schematic diagram illustrating the calculation of quartile and decile ranges, in accordance with some embodiments of the technology described herein.

FIG. 5A is a plot showing a representative measurement of insertion loss, in accordance with some embodiments of the technology described herein.

FIG. 5B is a plot showing a statistical visualization of measured insertion losses for multiple tested electrical devices, in accordance with some embodiments of the technology described herein.

FIG. 6A is a plot showing a representative measurement of return loss measured from near end to near end of a tested electrical device, in accordance with some embodiments of the technology described herein.

FIG. 6B is a plot showing a statistical visualization of measured return losses measured near end to near end for multiple tested electrical devices, in accordance with some embodiments of the technology described herein.

FIG. 7A is a plot showing a representative measurement of return loss measured from far end to far end of a tested electrical device, in accordance with some embodiments of the technology described herein.

FIG. 7B is a plot showing a statistical visualization of measured return losses measured far end to far end for multiple tested electrical devices, in accordance with some embodiments of the technology described herein.

FIG. 8A is a plot showing a representative measurement of near end crosstalk, in accordance with some embodiments of the technology described herein.

FIG. 8B is a plot showing a statistical visualization of measured near end crosstalk for multiple tested electrical devices, in accordance with some embodiments of the technology described herein.

FIG. 9A is a plot showing a representative measurement of far end crosstalk, in accordance with some embodiments of the technology described herein.

FIG. 9B is a plot showing a statistical visualization of measured far end crosstalk for multiple tested electrical devices, in accordance with some embodiments of the technology described herein.

FIG. 10A is a plot showing a representative measurement of impedance, in accordance with some embodiments of the technology described herein.

FIG. 10B is a plot showing a statistical visualization of measured impedances for multiple tested electrical devices, in accordance with some embodiments of the technology described herein.

FIG. 11 is a flowchart of a process 1100 for performing quality control in manufacture of a plurality of electrical components, in accordance with some embodiments of the technology described herein.

FIG. 12 is a diagram of an illustrative computer system, in accordance with some embodiments.

### DETAILED DESCRIPTION

When manufacturing electrical components at a high volume, quality control may be performed to ensure that each produced electrical device meets manufacturing specifications. This quality control may be implemented by performing one or more electrical measurements on each manufactured component to determine whether the electrical properties of each manufactured component falls within desired performance limits. However, the electrical characterization of each electrical device or a subset of the manufactured electrical devices often yields a large volume of data that may not be readily synthesized to inform quality control decisions. Rather, each electrical measurement may be stored separately such that manufacturing trends cannot be easily extrapolated from the individual electrical measurements.

The inventors have recognized and appreciated that the volume of data generated in the process of performing quality control for volume manufacturing may be unwieldy and unhelpful in making business and/or manufacturing decisions. The inventors have further recognized and appreciated that aggregating numerous measurements (e.g., from a manufacturing lot, date, shift, or other time period) in a single graphical representation may enable more insight into the manufacturing process and/or improved product quality. Accordingly, the inventors have developed techniques for performing quality control by determining and graphically representing quantile statistics calculated using electrical measurements characterizing multiple manufactured electrical components.

In some embodiments, the techniques describe herein include obtaining electrical characterization data describing an electrical property of multiple electrical components. The electrical characterization data may be obtained by measuring, for each electrical component and using test equipment, an electrical parameter. For example, to obtain a measurement from an electrical component, the test equipment may generate an electrical signal to be provided as input to the electrical component and the test equipment may measure output electrical signal received from the electrical component. The output electrical signal may be a transmitted electrical signal, a reflected electrical signal, and/or an electrical signal generated by crosstalk within the electrical component. The output electrical signal may be measured as a function of a parameter (e.g., frequency, amplitude, and/or phase (e.g., as in spectroscopy techniques) or time). The obtained measurements may be discrete functions including a set of data points that are pairs of measured values and parameter values.

In some embodiments, the obtained electrical characterization data may be a subset of all available electrical characterization data. The obtained electrical characterization data may be selected to provide insight into the electrical properties of a subset of the manufactured components. For example, the obtained electrical characterization data may be selected based on serial numbers associated with the electrical components, a date of manufacture of the electrical components, lot numbers, and/or a manufacturing shift during which time the electrical components were manufactured.

In some embodiments, the techniques described herein include determining quantile statistics for the obtained electrical characterization data. For example, the quantile statistics may include a median. The median may be calculated using the measured values determined by measuring the electrical properties of the electrical components. For example, for each parameter value in the sets of data points, the median may be calculated by determining a middle value using respective measured values.

In some embodiments, determining the quantile statistics may include determining one or more quantiles. For example, the quantiles may include a lower quantile defining a point below which a set percentage of the data is disposed. The statistical values may also include an upper quantile defining a point above which a set percentage of the data is disposed. For example, the quantiles may be one or more of terciles, quartiles, quintiles, sextiles, septiles, octiles, deciles, dodeciles, hexadeciles, percentiles, and/or any other suitable quantile values.

In some embodiments, the lower quantile and the upper quantile may be calculated using the obtained measurements and the calculated medians. For example, the lower quantile may comprise a quartile such that the lower quantile may be calculated by determining middle values between smallest values of the measured values and the medians of the measured values of the obtained measurements. As another example, the upper quantile may comprise a quartile such that the upper quantile may be calculated by determining middle values between the medians and the largest values of the measured values of the obtained measurements.

In some embodiments, the techniques include generating a graphical user interface containing a visualization of the determined quantile statistics of the electrical characterization data. The graphical representation may be generated using calculated quantile statistics such as, for example, the median and/or other quantile values including but not limited to terciles, quartiles, quintiles, sextiles, septiles, octiles, deciles, dodeciles, hexadeciles, percentiles, and/or any other suitable quantile values.

In some embodiments, generating the graphical representation may include generating a graph including shaded regions and/or lines representative of the determined quantile statistics. For example, the graph may include a line representative of the median values and one or more shaded regions or lines representative of other quantile statistics (e.g., terciles, quartiles, quintiles, sextiles, septiles, octiles, deciles, dodeciles, hexadeciles, percentiles, and/or any other suitable quantile values). Alternatively or additionally, the graph may include a first shaded region extending between lower quantile values and the upper quantile values, a second shaded region extending between the lower quantile values and smallest values of the measured values, and a third shaded region extending between the upper quantile values and largest values of the measured values. The first shaded region may be depicted using a first color and the second and third shaded regions may be depicted using a second color different from the first color.

In some embodiments, the techniques may further include identifying a quality control action to perform based on information in the graphical user interface containing the visualization of the determined quantile statistics. In some embodiments, visualizing the quantile statistics of the measured electrical properties of the electrical components may be performed contemporaneously with the manufacturing process (e.g., in real time, at the beginning and/or end of each shift, and/or daily) to provide feedback as manufacturing proceeds. This contemporaneous feedback may enable the identification of a maintenance action to maintain or fix a tool used in the manufacture of the plurality of electrical components. For example, measured impedances may shift over time as a hot bar used for soldering degrades such that the shifted impedances may be used to determine when to perform maintenance on the hot bar.

As another example, in some embodiments, identifying a quality control action may include identifying a maintenance action to maintain or fix the test equipment. Measured electrical properties may drift over time as connectors used to couple the testing equipment to the electrical components wear out over time. The drift of electrical properties may be used to determine when to replace inaccurate testing equipment so that testing data provided to customers accurately reflects the quality of the manufactured electrical components.

In some embodiments, identifying the quality control action comprises identifying a preferred production process to manufacture the plurality of electrical components. In some embodiments, identifying the quality control action comprises identifying a preferred supplier of a part used in manufacturing the plurality of electrical components. For example, a first lot of electrical components may be manufactured using a first manufacturing technique or a part obtained from a first supplier while a second lot of electrical components may be manufactured using a second manufacturing technique or a part obtained from a second supplier. Quantifying and visualizing the quantile statistics describing the electrical properties of the first lot and the second lot can assist in identifying differences in manufactured component quality as a result of different manufacturing techniques or part suppliers. By identifying differences in the completed components of the first and second lots, an informed decision may be made regarding the implementation of a particular manufacturing technique or the supplier from which to purchase parts.

In some embodiments, identifying the quality control action comprises identifying feedback to provide to a supplier of a part used in manufacturing the plurality of electrical components. For example, when manufacturing an electrical component using a spool of cable, the cable's electrical properties may differ along its length due to manufacturing variations. The electrical components manufactured using cable from one end of the cable may have different electrical properties than electrical components manufactured using cable from the other end of the cable, and these differences can be identified by visualizing quantile statistics describing the electrical properties of these different groups of electrical components. By identifying this change in electrical behavior, feedback may be provided to the cable supplier to mitigate the varying properties of the electrical cable.

Following below are more detailed descriptions of various concepts related to, and embodiments of, methods and apparatus for visualizing statistics describing electrical characterization of numerous electrical devices. It should be appreciated that various aspects described herein may be implemented in any of numerous ways. Examples of specific implementations are provided herein for illustrative purposes only. In addition, the various aspects described in the embodiments below may be used alone or in any combination and are not limited to the combinations explicitly described herein.

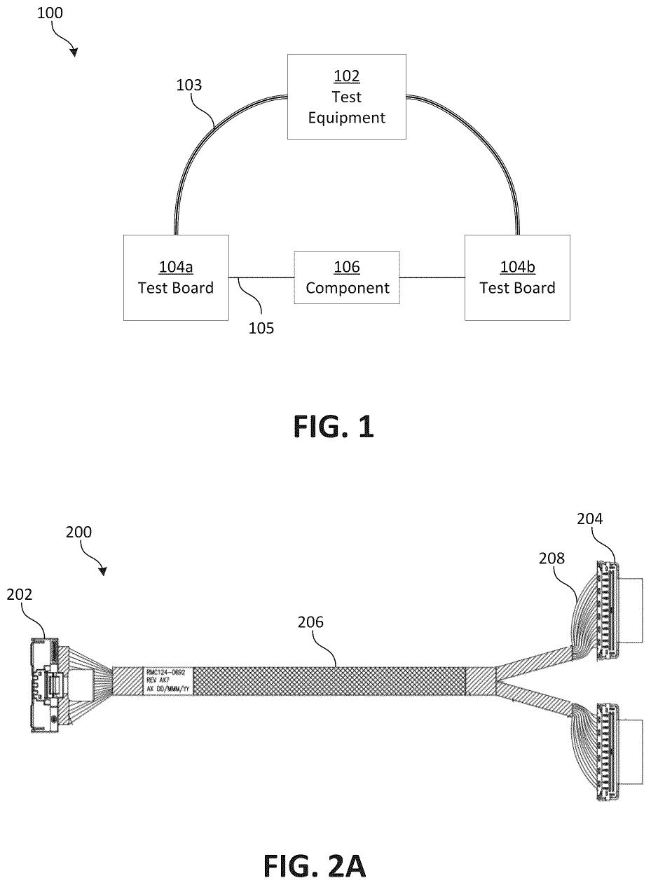

FIG. 1 is a schematic diagram of an electronic testing unit 100, in accordance with some embodiments of the technology described herein. The electronic testing unit 100 includes test equipment 102 coupled to a first test board 104a and a second test board 104b by connections 103. The connections 103 may be, for example, cables (e.g., coaxial cables, twisted pair cables, heliax cables, twinax cables, etc.) coupling the test equipment 102 to the first test board 104a and the second test board 104b. The first test board 104a and the second test board 104b may be, for example, printed circuit boards (PCBs) arranged to couple electrical signals between the connections 103 and the electrical component 106.

In some embodiments, the electrical component 106 may be coupled between the first test board 104a and the second test board 104b by connections 105. The connections 105 may be, for example, complementary receptacle and/or plug connectors that interface with the electrical component 106 and are coupled to the first test board 104a and the second test board 104b. Alternatively or additionally, the connections 105 may include cables (e.g., coaxial cables, twisted pair cables, heliax cables, twinax cables, etc.), in some embodiments.

In some embodiments, the test equipment 102 may be arranged to measure one or more electrical parameters of an electrical component 106 coupled to the first test board 104a and the second test board 104b by connections 105. The test equipment 102 may be able to transmit and receive electrical signals through the connections 103 to and from both the first test board 104a and second test board 104b such that the test equipment 102 may measure signals transmitted through and signals reflected by the electrical component 106. For example, the test equipment 102 may be arranged to measure one or more of scattering parameters (S-parameters), admittance parameters (Y-parameters), impedance parameters (Z-parameters), hybrid parameters (H-parameters), inverse hybrid parameters (G-parameters), and/or chain parameters (ABCD-parameters, also known as cascade parameters or transmission parameters) of the electrical component 106. In some embodiments, the test equipment 102 may be, for example, a network analyzer such as a vector network analyzer (VNA).

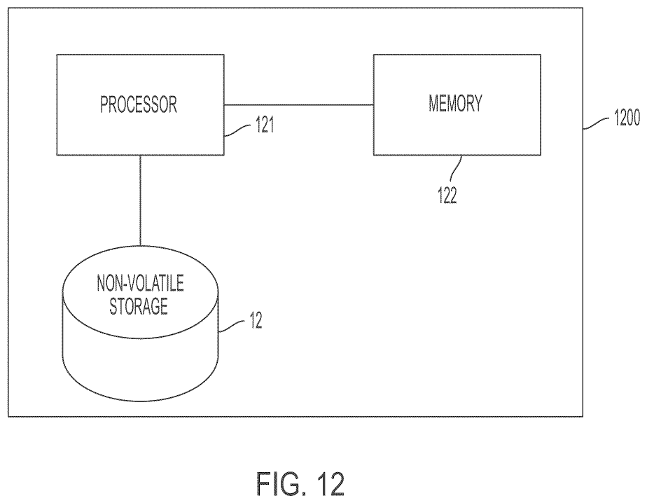

In some embodiments, the test equipment 102 may be configured to acquire electrical measurements characterizing the electrical component 106 and to generate one or more files storing raw data describing the acquired electrical measurements. For example, the test equipment 102 may include a computing device (e.g., as described in connection with FIG. 12) configured to store the acquired electrical measurements in computer memory. Alternatively or additionally, the test equipment 102 may be configured to transmit acquired electrical measurements to a separate computing device (not pictured) for storage and/or analysis.

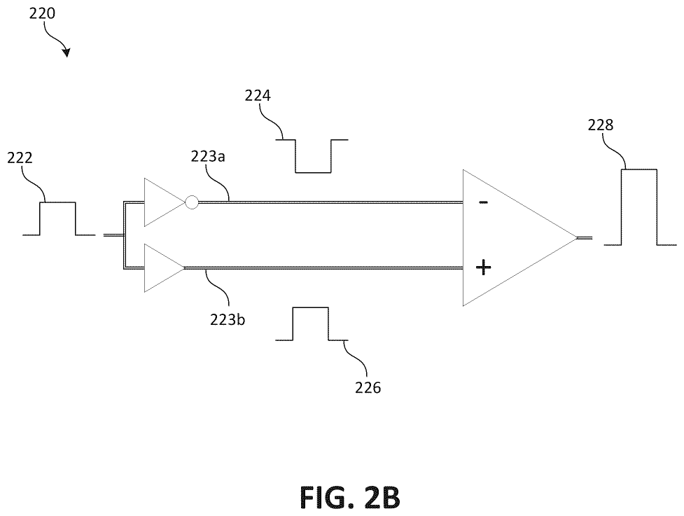

In some embodiments, the electrical component 106 may be a cable assembly. FIG. 2A depicts an illustrative cable assembly 200 configured for high-speed data transmission. The cable assembly 200 includes a first connector 202 coupled to second connectors 204 by a cable 206. When the cable assembly 200 is being tested using electronic testing unit 100, the first connector 202 may be coupled to the first test board 104a and the second connectors 204 may be coupled to the second test board 104b such that the first connector 202 may correspond to a “first end” of the cable assembly 200 and the second connectors 204 may correspond to a “second end” of the cable assembly 200.

In some embodiments, the cable 206 may be formed of multiple differential conductor pairs 208 terminated at either end of the cable assembly 200 in the first connector 202 and the second connectors 204. The multiple differential conductor pairs 208 may be arranged in the cable 206 in two rows that are stacked (e.g., a first set of multiple differential conductor pairs 208 may be arranged in a row in a first plane and a second set of multiple differential conductor pairs 208 may be arranged in a row in a second plane parallel to the first plane).

In some embodiments, the cable assembly 200 may be configured to operate using differential signaling techniques. FIG. 2B is a schematic circuit diagram 220 illustrating the principles of differential signaling. In differential signaling, an electrical signal is transmitted using two complementary electrical signals, known as a differential pair of signals. As shown in FIG. 2B, an input signal 222 may be provided to the differential pair of conductors having a first conductor 223a and a second conductor 223b. In the first conductor 223a, the input signal 222 may be inverted to form signal 224. In the second conductor 223b, the input signal 222 may remain non-inverted to form signal 226. At the output of the differential pair of conductors 223a and 223b, the signals 224 and 226 are recombined (e.g., by sensing a voltage difference between the signals 224 and 226), resulting in an output signal 228 having a larger amplitude than the input signal 222.

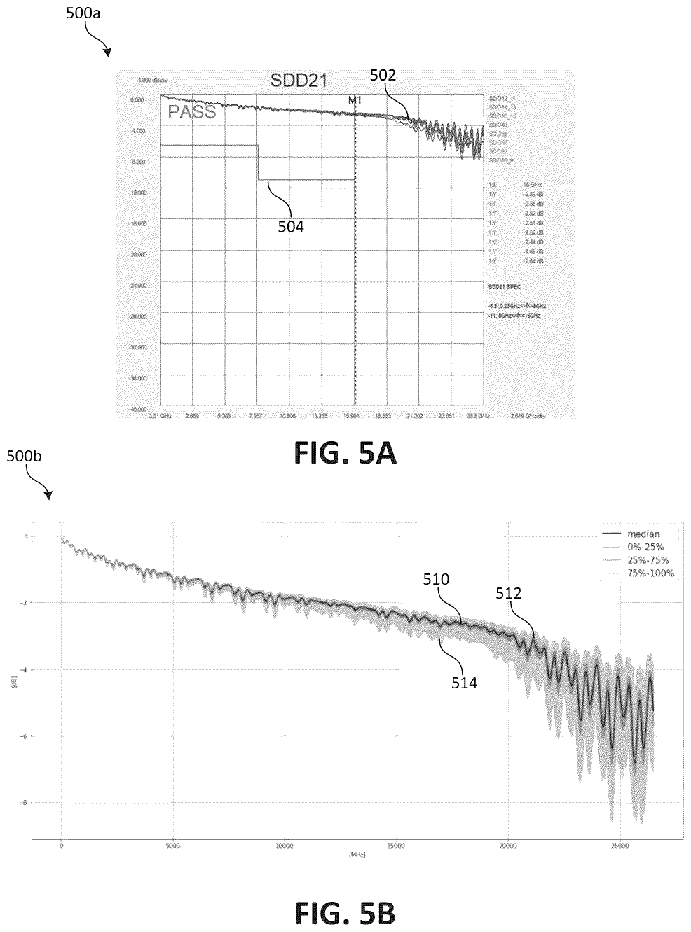

In some embodiments, when characterizing a cable assembly such as cable assembly 200, the electronic testing unit 100 may measure one or more electrical properties of the cable assembly 200. For example, the electronic testing unit 100 may be configured to measure one or more of impedance, insertion loss, return loss, far end crosstalk, near end crosstalk, far end component contribution integrated crosstalk noise, near end component contribution integrated crosstalk noise, impedance mix-mode parameters, and/or skew of the cable assembly, as described in more detail in connection with FIGS. 5A-10B herein. For each measurement, the electronic testing unit 100 may generate a data series of measured values, each associated with a fixed measurement point within a measurement interval of a parameter. The generated data series may be graphically represented as a plot showing the measured values as a function of the parameter.

For example, when measuring the insertion loss of the cable assembly, the electronic testing unit 100 may generate a data series of measured values of signal amplitude associated with fixed measurement points within a frequency interval (e.g., the measured values are a discrete function of frequency). As another example, when measuring an impedance of the cable assembly, the electronic testing unit 100 may generate a data series of measured values of resistance in Ohms associated with fixed measured points in time (e.g., the measured values are a discrete function of time). It should be appreciated that the measurement values may be a discrete function of other parameters than frequency or time (e.g., phase, amplitude, temperature, or any other suitable parameter), as aspects of the technology described herein are not limited in this respect.

In some embodiments, the electronic testing unit 100 may be used to characterize a large number of cable assemblies (e.g., tens, hundreds, thousands, tens of thousands, etc.). The electronic testing unit 100 may accordingly generate multiple data series of measured values associated with fixed measurement points within a measurement interval of a parameter. Graphically representing statistics associated with the multiple data series may provide additional information in comparison to graphically representing numerous individual measurements side-by-side or overlaid.

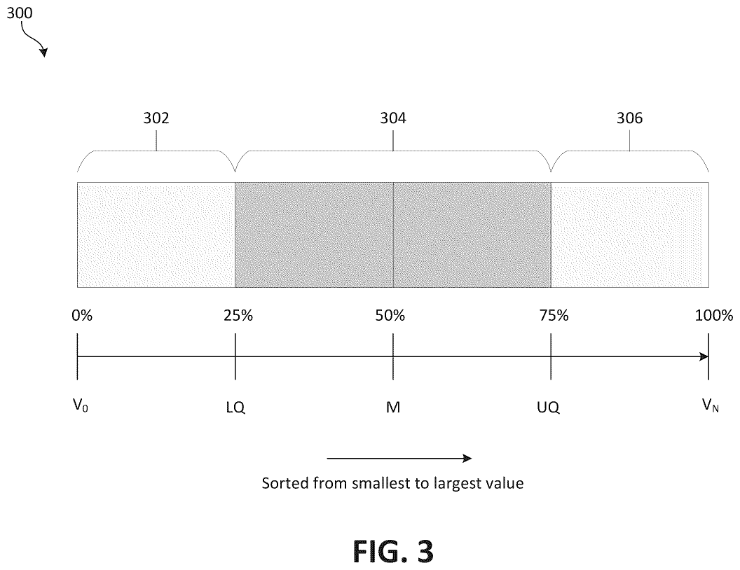

In particular, graphically representing quantile statistics of the acquired multiple data series may be useful to the manufacturer and/or customer. FIG. 3 is a schematic diagram 300 describing a calculation of illustrative quartile ranges, in accordance with some embodiments of the technology described herein. For each measurement point, the measured values acquired for all tested electrical components may be arranged from a smallest value, V₀, to a largest value, V_{N}. As an example, for a time point t=1.0 ns in the measurement interval, all measured values of the signal amplitude may be arranged in order from the smallest value to the largest value of signal amplitude. Based on these arranged measured values, a median, M, may be calculated. The median is the value separating the upper 50% of the measured values from the lower 50% of the measured values. For a set of arranged measured values having an odd number of measured values, M may be calculated by determining a middle value. For a set of arranged measured values having an even number of measured values, M may be calculated by taking an average of the two middle values.

In some embodiments, after calculating the median, M, a lower quantile value, LQ, and an upper quantile value, UQ, may be calculated using the arranged measured values and the median, M. As shown in the example of FIG. 3, the lower quantile value, LQ, and an upper quantile value, UQ, may be lower quartile and upper quartile values, respectively. The lower quartile value separates the lowest 25% of the arranged measured values, shown as region 302, from the upper 75% of the arranged measured values. The upper quartile value separates the upper 25% of the arranged measured values, shown as region 306, from the lower 75% of the arranged measured values. The middle 50% of the arranged measured values, shown as region 304, are located between the lower and upper quartile values. It should be appreciated that the lower quantile value, LQ, and an upper quantile value, UQ, may be different quantiles than quartiles (e.g., one or more of terciles, quartiles, quintiles, sextiles, septiles, octiles, deciles, dodeciles, hexadeciles, percentiles, and/or any other suitable quantile values), as aspects of the technology described herein are not limited in this respect.

Returning to the example of FIG. 3, the lower and upper quartile values may be calculated according to one of several methods. In a first method, the median, M, is used to divide the arranged measured values into two halves. If there is an odd number of data points in the arranged measured values, the median is not included in either half. If there is an even number of data points in the arranged measured values, the data may be split exactly in half. The lower quartile value may then be calculated by determining the median of the lower half of the data (e.g., the half of the data between the smallest value, V₀, and the median, M). The upper quartile value may then be calculated by determining the median of the upper half of the data (e.g., the half of the data between the median, M, and the largest value, V_{N}).

In some embodiments, a second method may be used to calculate the lower and upper quartile values. The median, M, is used to divide the arranged measured values into two halves. If there is an odd number of data points in the arranged measured values, the median is included in both halves of the data. If there is an even number of data points in the arranged measured values, the data may be split exactly in half. The lower quartile value may then be calculated by determining the median of the lower half of the data (e.g., the half of the data between the smallest value, V₀, and the median, M). The upper quartile value may then be calculated by determining the median of the upper half of the data (e.g., the half of the data between the median, M, and the largest value, V_{N}).

In some embodiments, a third method may be used to calculate the lower and upper quartile values. The median, M, is used to divide the arranged measured values into two halves. If there is an even number of data points in the arranged measured values, the arranged measured values may be split exactly into two halves. If there are an odd number of data points, the median, M, may or may not be included as a data point in each half of the data. If the median, M, is included in each half of the data, then:
1. If there are (4n+1) data points, then the lower quartile value, LQ, is 25% of the n^{th} data value plus 75% of the (n+1)^{th} data value, and the upper quartile value, UQ, is 75% of the (3n+1)^{th} data value plus 25% of the (3n+2)^{th} data value.
2. If there are (4n+3) data points, then the lower quartile value, LQ, is 75% of the (n+1)^{th} data value plus 25% of the (n+2)^{th} data value, and the upper quartile value, UQ, is 25% of the (3n+2)^{th} data value plus 75% of the (3n+3)^{th} data value.

In some embodiments, a fourth method may be used to calculate the lower and upper quartile values. For an ordered dataset of arranged measured values, V₀, V₁, . . . , V_{N}, an interpolation between the data points may be made to find the p^{th} empirical quantile if V₀ is in the i/(n+1) quantile. Denoting the integer part of a number a as └a┘, the empirical quantile function is given by:

$$q ( \frac{p}{4} ) = {x}_{k} + α ( {x}_{k + 1} - {x}_{k} )$$

where k=└p(n+1)/4┘ and α=p(n+1)/4−└p(n+1)/4┘. Using this framework, calculating the lower quartile value, LQ, the median, M, and the upper quartile value, UQ, may be implemented by evaluating q(0.25), q(0.5), and q(0.75), respectively.

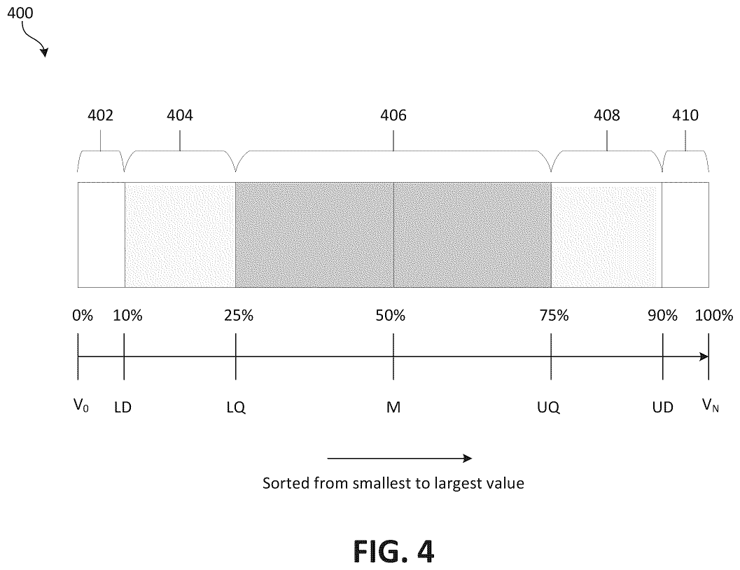

It should be appreciated that the techniques described herein are not limited to the calculation of, and visualization of, quartile statistics, as aspects of the technology are not limited in this respect. Rather, the techniques described herein may be implemented using terciles, quartiles, quintiles, sextiles, septiles, octiles, deciles, dodeciles, hexadeciles, percentiles, and/or any other suitable quantile values. As a further example, FIG. 4 is a schematic diagram 400 illustrating the calculation of quartile and decile statistics, in accordance with some embodiments of the technology described herein. Calculating smaller quantile statistics may be helpful in determining the effect of outliers on the distribution of electrical components, which in turn may be informative in determining how much product to discard in the case that outliers fail to meet quality standards.

The example of FIG. 4 includes the same median, M, lower quantile value, LQ, and upper quantile value, UQ, as the example described in connection with FIG. 3 herein. However, the example of FIG. 4 further includes a lower decile value, LD, and an upper decile value, UD. The lower decile value separates the lowest 10% of the arranged measured values, shown as region 402, from the upper 90% of the arranged measured values. The upper decile value separates the upper 10% of the arranged measured values, shown as region 410, from the lower 90% of the arranged measured values. As in the example of FIG. 3, the middle 50% of the arranged measured values, shown as region 406, are located between the lower and upper quartile values. Additional regions 404 and 408 demarcate the regions including the lowest 10% to lowest 25% of the arranged measured values and the highest 25% to highest 10% of the arranged measured values, respectively.

In some embodiments, and as discussed in connection with the examples of FIGS. 1 and 2, the electrical components being manufactured may be cable assemblies including multiple differential pairs of conductors. The cable assemblies may be configured to support high speed data transfer (e.g., 10 Gbps, 12 Gbps, 24 Gbps, or other speeds having a frequency in the GHz range). To characterize such cable assemblies, or other electrical components configured to support high speed data transfer, a number of electrical properties may be measured. For example, insertion loss, return loss, far end crosstalk, near end crosstalk, far end component contribution integrated crosstalk noise, near end component contribution integrated crosstalk noise, impedance mix-mode parameters, and/or skew of the cable assemblies may be measured using the test equipment.

FIG. 5A is a plot 500a showing representative measurements 502 of insertion loss, in accordance with some embodiments described herein. Insertion loss is a parameter describing the degradation of a transmitted signal from a first end (“near end”) of the electrical component to a second end (“far end”) of the electrical component. To measure insertion loss in a cable assembly including differential pairs of conductors, a differential electrical signal may be provided as input to the cable assembly and transmitted through a differential pair of conductors from a first end of the cable assembly to the second end of the cable assembly. The input differential electrical signal may include two electrical signals that are in a differential mode (e.g., 180 degrees out of phase with one another), each of the two electrical signals being provided to a separate conductor of the differential pair of conductors.

In some embodiments, the test equipment may perform frequency-based spectroscopy to measure the insertion loss such that the measured signal amplitude may be a function of frequency. For example, the frequency of the input differential electrical signal may be increased (or decreased) by a fixed frequency step during the insertion loss measurement. In some embodiments, the frequency of the input differential electrical signal may be changed by constant intervals of 1 MHz, 10 MHz, 20 MHz, and/or 25 MHz. An amplitude of the transmitted signal may then be measured at the second side of the cable assembly for each frequency value.

FIG. 5B is a plot 500b showing quantile statistics of insertion loss measured in multiple cable assemblies, in accordance with some embodiments of the technology described herein. The plot 500b includes a curve 510 indicating a median of the measured amplitude. The shaded region 512 indicates the center 50% of the measured amplitude data (e.g., from a lower quartile value to an upper quartile value). The shaded region 514 indicates the lowest 25% of the measured amplitude data (e.g., from the lower quartile value to a smallest value) and the upper 25% of the measured amplitude data (e.g., from the upper quartile value to a largest value).

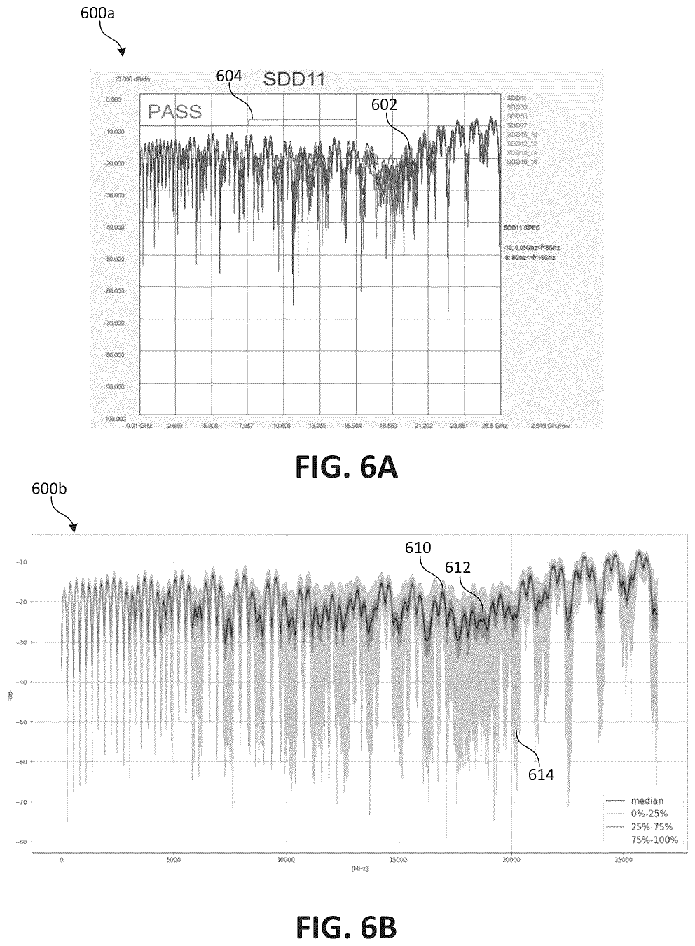

FIG. 6A is a plot 600a showing representative measurements 602 of return loss, in accordance with some embodiments of the technology described herein. Return loss is a parameter describing how much energy is returning to the source as the primary signal travels forward through the electrical component. Return loss is therefore measured by providing an input differential electrical signal at a first end (“near end”) of the cable assembly and measuring the reflected signal at the same first end of the cable assembly. The input differential electrical signal may include two electrical signals that are in a differential mode (e.g., 180 degrees out of phase with one another), each of the two electrical signals being provided to a separate conductor of the differential pair of conductors.

In some embodiments, the test equipment may perform frequency-based spectroscopy to measure the return loss such that the measured reflected signal amplitude may be a function of frequency. For example, the frequency of the input differential electrical signal may be increased (or decreased) by a fixed frequency step during the return loss measurement. In some embodiments, the frequency of the input differential electrical signal may be changed by constant intervals of 1 MHz, 10 MHz, 20 MHz, and/or 25 MHz. An amplitude of the reflected signal may then be measured at the first side of the cable assembly for each frequency value.

FIG. 6B is a plot 600b showing quantile statistics of return loss measured in multiple cable assemblies, in accordance with some embodiments of the technology described herein. The plot 600b includes a curve 610 indicating a median of the measured amplitude. The shaded region 612 indicates the center 50% of the measured amplitude data (e.g., from a lower quartile value to an upper quartile value). The shaded region 614 indicates the lowest 25% of the measured amplitude data (e.g., from the lower quartile value to a smallest value) and the upper 25% of the measured amplitude data (e.g., from the upper quartile value to a largest value).

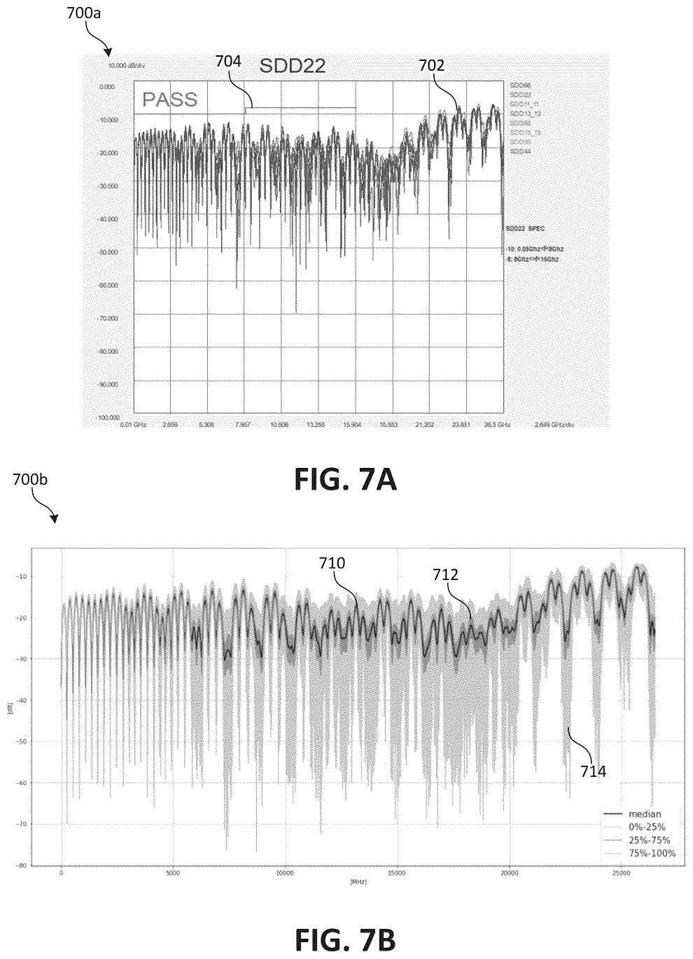

FIG. 7A is a plot 700a showing representative measurements 702 of far end return loss, in accordance with some embodiments of the technology described herein. Far end return loss is a parameter describing how much energy is returning to the receiver as the primary signal travels forward through the electrical component away from the receiver. Far end return loss is therefore measured by providing an input differential electrical signal at a second end (“far end”) of the cable assembly and measuring the reflected signal at the same second end of the cable assembly. The input differential electrical signal may include two electrical signals that are in a differential mode (e.g., 180 degrees out of phase with one another), each of the two electrical signals being provided to a separate conductor of the differential pair of conductors.

In some embodiments, the test equipment may perform frequency-based spectroscopy to measure the far end return loss such that the measured reflected signal amplitude may be a function of frequency. For example, the frequency of the input differential electrical signal may be increased (or decreased) by a fixed frequency step during the far end return loss measurement. In some embodiments, the frequency of the input differential electrical signal may be changed by constant intervals of 1 MHz, 10 MHz, 20 MHz, and/or 25 MHz. An amplitude of the reflected signal may then be measured at the second side of the cable assembly for each frequency value.

FIG. 7B is a plot 700b showing quantile statistics of far end return loss measured in multiple cable assemblies, in accordance with some embodiments of the technology described herein. The plot 700b includes a curve 710 indicating a median of the measured amplitude. The shaded region 712 indicates the center 50% of the measured amplitude data (e.g., from a lower quartile value to an upper quartile value). The shaded region 714 indicates the lowest 25% of the measured amplitude data (e.g., from the lower quartile value to a smallest value) and the upper 25% of the measured amplitude data (e.g., from the upper quartile value to a largest value).

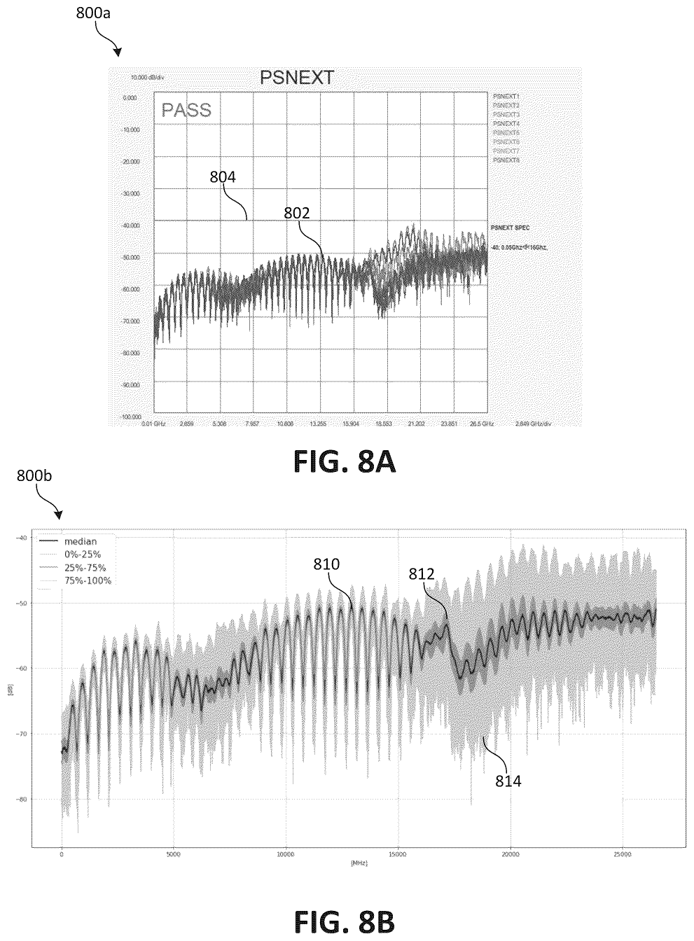

FIG. 8A is a plot 800a showing representative measurements 802 of near end crosstalk, in accordance with some embodiments of the technology described herein. Near end crosstalk is a parameter describing how much energy is radiated to an adjacent non-energized differential pair of conductors as an electrical signal travels forward through an energized differential pair of conductors. Near end crosstalk is therefore measured by providing an input differential electrical signal at a first end (“near end”) of the cable assembly and to a first differential pair of conductors. The near end crosstalk is then measured at the first end of the cable assembly on a second differential pair of conductors that is located adjacent the first differential pair of conductors (e.g., in a parallel row of differential pairs of conductors). The input differential electrical signal may include two electrical signals that are in a differential mode (e.g., 180 degrees out of phase with one another), each of the two electrical signals being provided to a separate conductor of the first differential pair of conductors.

In some embodiments, the test equipment may perform frequency-based spectroscopy to measure the near end crosstalk such that the measured signal amplitude may be a function of frequency. For example, the frequency of the input differential electrical signal may be increased (or decreased) by a fixed frequency step during the near end crosstalk measurement. In some embodiments, the frequency of the input differential electrical signal may be changed by constant intervals of 1 MHz, 10 MHz, 20 MHz, and/or 25 MHz. An amplitude of the radiated signal may then be measured at the first side of the cable assembly in a second, non-energized differential pair of conductors for each frequency value.

FIG. 8B is a plot 800b showing quantile statistics of near end crosstalk measured in multiple cable assemblies, in accordance with some embodiments of the technology described herein. The plot 800b includes a curve 810 indicating a median of the measured amplitude. The shaded region 812 indicates the center 50% of the measured amplitude data (e.g., from a lower quartile value to an upper quartile value). The shaded region 814 indicates the lowest 25% of the measured amplitude data (e.g., from the lower quartile value to a smallest value) and the upper 25% of the measured amplitude data (e.g., from the upper quartile value to a largest value).

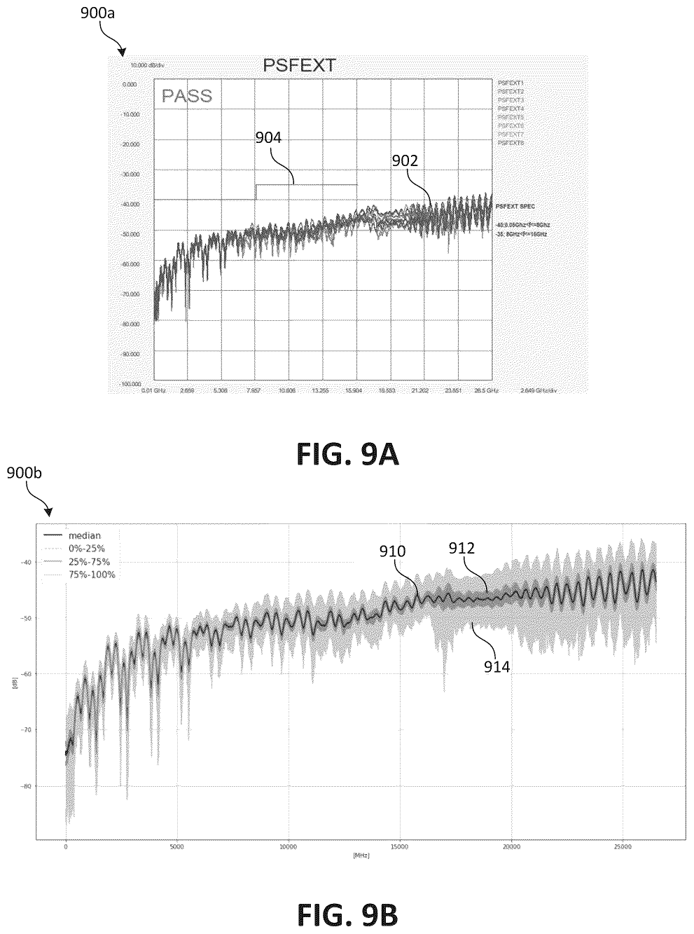

FIG. 9A is a plot 900a showing representative measurements 902 of far end crosstalk, in accordance with some embodiments of the technology described herein. Far end crosstalk is a parameter describing how much energy is radiated to an adjacent non-energized differential pair of conductors as an electrical signal travels forward through an energized differential pair of conductors. Far end crosstalk is therefore measured by providing an input differential electrical signal at a first end (“near end”) of the cable assembly and to a first differential pair of conductors. The far end crosstalk is then measured at the second end of the cable assembly on a second differential pair of conductors that is located adjacent the first differential pair of conductors (e.g., in a parallel row of differential pairs of conductors). The input differential electrical signal may include two electrical signals that are in a differential mode (e.g., 180 degrees out of phase with one another), each of the two electrical signals being provided to a separate conductor of the first differential pair of conductors.

In some embodiments, the test equipment may perform frequency-based spectroscopy to measure the far end crosstalk such that the measured signal amplitude may be a function of frequency. For example, the frequency of the input differential electrical signal may be increased (or decreased) by a fixed frequency step during the far end crosstalk measurement. In some embodiments, the frequency of the input differential electrical signal may be changed by constant intervals of 1 MHz, 10 MHz, 20 MHz, and/or 25 MHz. An amplitude of the radiated signal may then be measured at the first side of the cable assembly in a second, non-energized differential pair of conductors for each frequency value.

FIG. 9B is a plot 900b showing quantile statistics of far end crosstalk measured in multiple cable assemblies, in accordance with some embodiments of the technology described herein. The plot 900b includes a curve 910 indicating a median of the measured amplitude. The shaded region 912 indicates the center 50% of the measured amplitude data (e.g., from a lower quartile value to an upper quartile value). The shaded region 914 indicates the lowest 25% of the measured amplitude data (e.g., from the lower quartile value to a smallest value) and the upper 25% of the measured amplitude data (e.g., from the upper quartile value to a largest value).

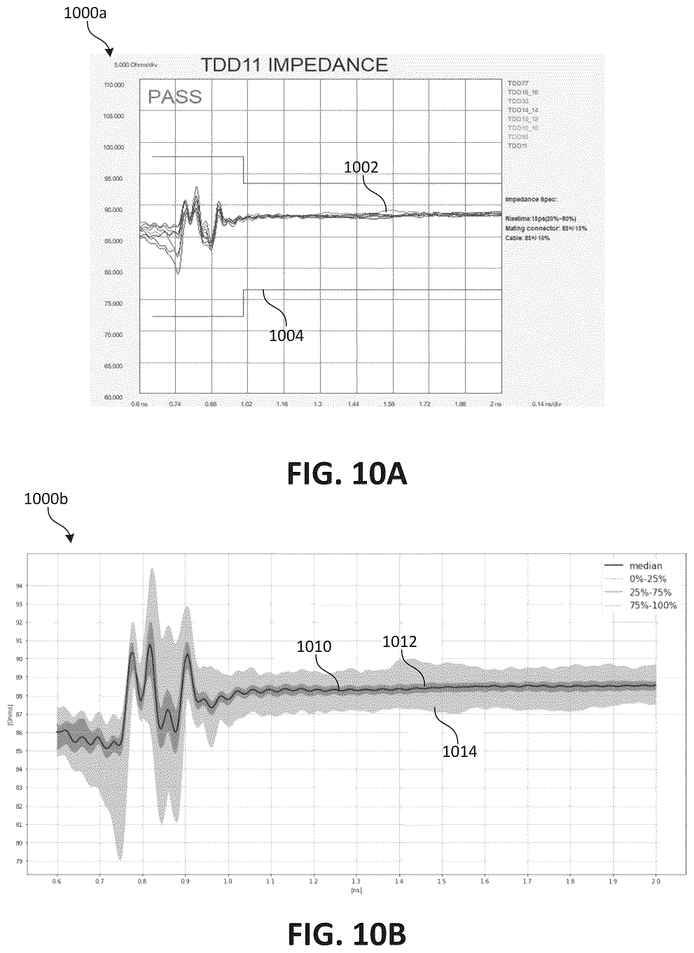

FIG. 10A is a plot 1000a showing representative measurements 1002 of impedance, in accordance with some embodiments of the technology described herein. Impedance is a parameter describing an effective resistance of the cable assembly and provides a measure of an imbalance in the coupling of the electromagnetic field around a differential pair of conductors. Impedance may be measured using time domain reflectometry. Thus, impedance may be measured by providing an input differential electrical signal at a first end (“near end”) of the cable assembly. The impedance is then measured by measuring a reflected signal received at the first end of the cable assembly on the same differential pair of conductors as used to transmit the input differential electrical signal. The input differential electrical signal may include two electrical signals that are in a differential mode (e.g., 180 degrees out of phase with one another), each of the two electrical signals being provided to a separate conductor of the first differential pair of conductors. To measure the impedance, the input differential electrical signal may have a fixed frequency equal to the Nyquist frequency of the data rate associated with the electrical component when it will be in operation.

FIG. 10B is a plot 1000b showing quantile statistics of impedance measured in multiple cable assemblies, in accordance with some embodiments of the technology described herein. The plot 1000b includes a curve 1010 indicating a median of the measured amplitude. The shaded region 1012 indicates the center 50% of the measured amplitude data (e.g., from a lower quartile value to an upper quartile value). The shaded region 1014 indicates the lowest 25% of the measured amplitude data (e.g., from the lower quartile value to a smallest value) and the upper 25% of the measured amplitude data (e.g., from the upper quartile value to a largest value).

In addition to the above-described electrical measurements, the test equipment may alternatively or additionally measure mix-mode parameters (not shown), in some embodiments. The mix-mode parameters describe a relationship between input differential energy and output common mode energy, which may arise if the two electrical signals forming the differential electrical signal are no longer 180 degrees out of phase upon measurement (e.g., due to differences in electrical length of the two conductors of the differential pair). Accordingly, to measure the mix-mode parameters of a cable assembly, the test equipment may provide an input differential electrical signal at a first end (“near end”) of the cable assembly. The mix-mode parameters are then measured at the second end of the cable assembly by measuring the common mode signal. The input differential electrical signal may include two electrical signals that are in a differential mode (e.g., 180 degrees out of phase with one another).

In some embodiments, the test equipment may alternatively or additionally measure skew parameters (not shown). Skew parameters describe whether the two conductors of a differential pair of conductors have a same physical and/or electrical length, such that the two transmitted signals remain synchronized during transmission. In some embodiments, skew parameters may be measured in either the time domain, using time domain reflectometry (TDR) or time domain transmissometry (TDT). In some embodiments, skew parameters may be measured in the frequency domain.

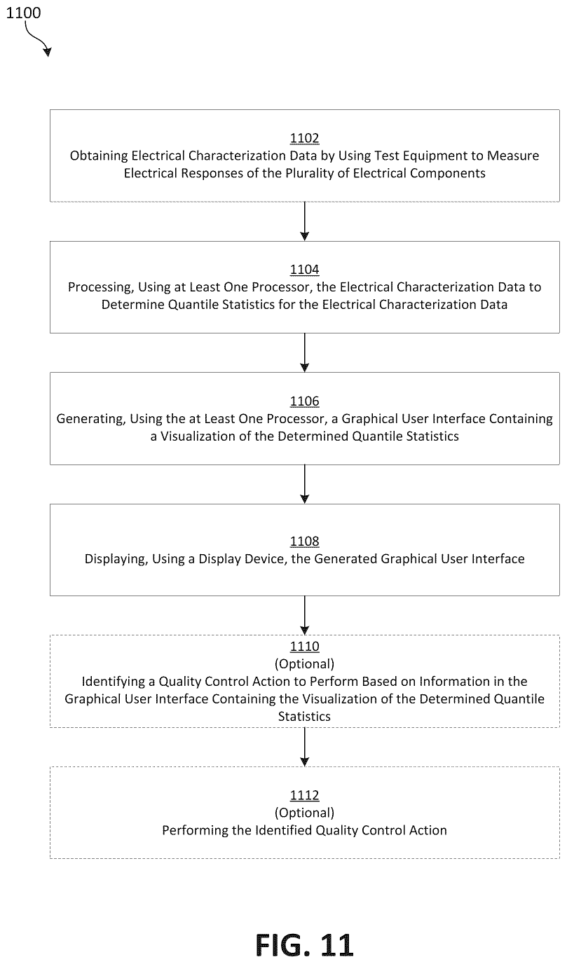

FIG. 11 is a flowchart of a process 1100 for performing quality control in manufacture of a plurality of electrical components, in accordance with some embodiments of the technology described herein. The process 1100 may be executed using any suitable computing device. For example, in some embodiments, the process 1100 may be performed by a computing device contained within the test equipment (e.g., test equipment 102) used to measure the electrical properties of the electrical components. In some embodiments, the process 1100 may be performed by a computing device communicatively coupled to the test equipment, either locally (e.g., over a local access network or by direct connection to the test equipment) or remotely (e.g., over a cloud computing environment).

In some embodiments, process 1100 may begin at act 1102, in which electrical characterization data may be obtained by using test equipment to measure electrical responses of the plurality of electrical components. The test equipment may be configured to generate an electrical stimulus signal, to provide the electrical stimulus signal to the electrical component under test, and to measure a reflected or transmitted signal output by the electrical component.

In some embodiments, the electrical components may be cable assemblies including differential pairs of conductors. The test equipment may therefore be configured to generate a differential electrical signal to be provided as input to the cable assembly under test. In some embodiments, the test equipment may be configured to measure one of a selection of impedance, insertion loss, return loss, integrated return loss, far end crosstalk, near end crosstalk, far end component contribution integrated crosstalk noise, near end component contribution integrated crosstalk noise, mix-mode parameters, noise rejection, and/or skew of the cable assemblies. These electrical parameters may be measured using techniques as described in connection with FIGS. 5A-10B herein.

In some embodiments, the measured electrical response of the electrical component may be a discrete function of a parameter (e.g., frequency, time, phase, temperature, etc.), the discrete function comprising a set of data points comprising pairs of measured values and parameter values. In some embodiments, the pairs of measured values and parameter values comprise pairs of measured signal amplitude values and time values, pairs of measured signal amplitude values and frequency values, and/or pairs of measured impedance values and time values.

In some embodiments, obtaining the electrical characterization data also includes selecting a subset of the measured electrical characterization data. For example, a subset of the measured electrical characterization data may be selected based on serial numbers associated with the plurality of electrical components, a date of manufacture of the plurality of electrical components, lot numbers associated with the plurality of electrical components, the machine(s) used to manufacture the plurality of electrical components, the supplier of one or more components used to assemble the plurality of electrical components, operators who manufactured the plurality of electrical components, the customer name, the tester, the test date, the test equipment, and/or manufacturing shifts associated with a time of manufacture of the plurality of electrical components.

In some embodiments, the electrical characterization data may be stored in a suitable data structure and/or file format for later processing. For example, the electrical characterization data may be stored as a comma-separated values (.csv) file, an Excel (.xls or .xlsx) file, and/or a Snapshot (.snp) file.

In some embodiments, after act 1102, process 1100 may proceed to act 1104, in which an at least one processor of the computing device processes the electrical characterization data to determine quantile statistics for the electrical characterization data. The at least one processor of the computing device may determine quantile statistics for the electrical characterization data by arranging, for each parameter value (e.g., each frequency step, each time point), the measured values from a smallest value to a largest value to obtain arranged measured values. Using the arranged measured values, the at least one processor may proceed to determine the quantile statistics as described in connection with FIGS. 3 and 4 herein. For example, the at least one processor may calculate a median of the measured values, a quartile, a decile, or any other suitable quantile, as a function of the parameter value.

In some embodiments, the at least one processor may further calculate additional statistics related to the measured values. For example, the at least one processor may calculate maximum and/or minimum limits of the measured values for later display alongside the quantile statistics in following act 1106 (e.g., the limits may be displayed as horizontal or vertical lines alongside the quantile statistics). As another example, the at least one processor may calculate, using any suitable methodology, a process capability index (CPK) based on the measured values and a provided lower specification limit (LSL) and a provided upper specification limit (USL).

In some embodiments, after act 1104, process 1100 may proceed to act 1106, in which the at least one processor of the computing device may generate a graphical user interface containing a visualization of the determined quantile statistics. Generating the graphical user interface may include generating a graph including one or more shaded regions or lines representative of the determined quantile statistics from act 1104. For example, if the at least one processor determined median statistics, the graphical user interface may be generated by generating a line representative of the determined median statistics. As another example, if the at least one processor determined quantile statistics other than the median statistics, the graphical user interface may be generated by generating one or more shaded regions representing the determined quantile statistics. In some embodiments, a first color may be assigned to a first shaded region representative of a first quantile and a second, different color may be assigned to a second shaded region representative of a second quantile.

In some embodiments, generating the graphical user interface containing a visualization of the determined quantile statistics may include generating a visualization of the median statistics and quartile statistics. For example, the visualization may include a line representative of the determined median statistics, a first shaded region representative of the region between the lower quartile and the upper quartile (e.g., the center 50% of the electrical characterization data), and a second shaded region representative of the regions between the lower quartile and smallest values of the electrical characterization data and between the upper quartile and largest values of the electrical characterization data (e.g., the lower 25% and upper 25% of the electrical characterization data. A first color may be assigned to the first shaded region representative of a first quantile and a second, different color may be assigned to the second shaded region representative of a second quantile.

In some embodiments, after act 1106, process 1100 may proceed to act 1108, in which a display device is used to display the generated graphical user interface. The display device may be any suitable electronic display, including but not limited to a computer monitor, laptop screen, mobile displays (e.g., of mobile devices including tablets), and/or smartphone displays. In some embodiments, the displayed graphical user interface may be configured to be zoomable such that a user may enlarge or decrease in size a portion of the displayed visualization of the quantile statistics.

In some embodiments, after act 1108, process 1100 may optionally proceed to act 1110, in which a quality control action to perform may be identified based on the information in the graphical user interface containing the visualization of the determined quantile statistics. In some embodiments, the identification of a quality control action may include the identification of a maintenance action to maintain or fix a tool used in the manufacture of the plurality of electrical components. For example, measured impedances may shift over time as a hot bar used for soldering degrades such that the shifted impedances may be used to determine when to perform maintenance on the hot bar.

As another example, in some embodiments, identifying a quality control action may include identifying a maintenance action to maintain or fix the test equipment. Measured electrical properties may drift over time as connectors used to couple the testing equipment to the electrical components wear out over time. The drift of electrical properties may be used to determine when to replace inaccurate testing equipment so that testing data provided to customers accurately reflects the quality of the manufactured electrical components.

In some embodiments, identifying the quality control action comprises identifying a preferred production process to manufacture the plurality of electrical components. In some embodiments, identifying the quality control action comprises identifying a preferred supplier of a part used in manufacturing the plurality of electrical components. For example, a first lot of electrical components may be manufactured using a first manufacturing technique or a part obtained from a first supplier while a second lot of electrical components may be manufactured using a second manufacturing technique or a part obtained from a second supplier. Quantifying and visualizing the quantile statistics describing the electrical properties of the first lot and the second lot can assist in identifying differences in manufactured component quality as a result of different manufacturing techniques or part suppliers. By identifying differences in the completed components of the first and second lots, an informed decision may be made regarding the implementation of a particular manufacturing technique or the supplier from which to purchase parts.

In some embodiments, identifying the quality control action comprises identifying feedback to provide to a supplier of a part used in manufacturing the plurality of electrical components. For example, when manufacturing an electrical component using a spool of cable, the cable's electrical properties may differ along its length due to manufacturing variations. The electrical components manufactured using cable from one end of the cable may have different electrical properties than electrical components manufactured using cable from the other end of the cable, and these differences can be identified by visualizing quantile statistics describing the electrical properties of these different groups of electrical components. By identifying this change in electrical behavior, feedback may be provided to the cable supplier to mitigate the varying properties of the electrical cable.

In some embodiments, after act 1110, process 1100 may optionally proceed to act 1112, in which the identified quality control action may be performed. For example, a maintenance action may be performed to maintain and/or fix a manufacturing tool or the test equipment. Alternatively or additionally, a selection of a manufacturing process and/or a selection of an external supplier of parts may be made. Alternatively or additionally, feedback may be provided to an external supplier to improve a quality of purchased parts incorporated into the electrical components.

FIG. 12 is a diagram of an illustrative computer system on which embodiments described herein may be implemented. An illustrative implementation of a computer system 1200 that may be used in connection with any of the embodiments of the disclosure provided herein is shown in FIG. 12. In some embodiments, any one of the processes described herein may be implemented on and/or using the computer system 1200. The computer system 1200 may include one or more processors 1210 and one or more articles of manufacture that comprise tangible (e.g., non-transitory) computer-readable storage media (e.g., memory 1220 and one or more non-volatile storage media 1230). The processor 1210 may control writing data to and reading data from the memory 1220 and the non-volatile storage device 1230 in any suitable manner. To perform any of the functionality described herein, the processor 1210 may execute one or more processor-executable instructions stored in one or more non-transitory computer-readable storage media (e.g., the memory 1220), which may serve as non-transitory computer-readable storage media storing processor-executable instructions for execution by the processor 1210.

Having thus described several aspects and embodiments of the technology set forth in the disclosure, it is to be appreciated that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the data and/or one or more of the advantages described herein, and each of such variations and/or modifications is deemed to be within the scope of the embodiments described herein. Those skilled in the art will recognize or be able to ascertain using no more than routine experimentation many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments can be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media can be transportable, such that the program or programs stored thereon can be loaded onto one or more different computers or other processors to implement various ones of the aspects described above. In some embodiments, computer readable media may be tangible (e.g., non-transitory) computer readable media. In some embodiments, the computer readable media may comprise a persistent memory.

The terms “program” or “software” are used herein in a generic sense to refer to any type of computer code or set of computer-executable instructions that can be employed to program a computer or other processor to implement various aspects as described above. Additionally, it should be appreciated that according to one aspect, one or more computer programs that when executed perform methods of the present disclosure need not reside on a single computer or processor but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone, or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately” and “about” may be used to mean within ±20% of a target value in some embodiments, within ±10% of a target value in some embodiments, within ±5% of a target value in some embodiments, within ±2% of a target value in some embodiments. The terms “approximately” and “about” may include the target value.

What is claimed is:

1. A method of performing quality control in manufacture of a plurality of electrical components, the method comprising:
obtaining electrical characterization data by using test equipment to measure electrical responses of the plurality of electrical components;
processing, using at least one processor, the electrical characterization data to determine quantile statistics for the electrical characterization data;
generating, using the at least one processor, a graphical user interface containing a visualization of the determined quantile statistics; and
displaying, using a display device, the generated graphical user interface.

2. The method of claim 1, further comprising:
identifying a quality control action to perform based on information in the graphical user interface containing the visualization of the determined quantile statistics.

3. The method of claim 2, further comprising:
performing the identified quality control action.

4. The method of claim 2, wherein identifying the quality control action comprises one or more of:
identifying a maintenance action to perform maintenance on a tool used in the manufacture of the plurality of electrical components;
identifying a selection of a production process to manufacture the plurality of electrical components;
identifying a maintenance action to perform maintenance on the test equipment;
identifying a selection of a supplier of a part used in manufacturing the plurality of electrical components; and/or
identifying feedback to provide to a supplier of a part used in manufacturing the plurality of electrical components.

5. The method of claim 1, wherein measuring an electrical response of an electrical component of the plurality of electrical components comprises:
generating, using the test equipment, an electrical stimulus signal;
providing the electrical stimulus signal as input to the electrical component; and
measuring, using the test equipment, a reflected or transmitted signal output by the electrical component.

6. The method of claim 1, wherein measuring an electrical response of an electrical component of the plurality of electrical components comprises measuring an electrical response comprising a discrete function of a parameter, the discrete function comprising a set of data points comprising pairs of measured values and parameter values.

7. The method of claim 6, wherein the pairs of measured values and parameter values comprise pairs of measured signal amplitude values and time values, pairs of measured signal amplitude values and frequency values, and/or pairs of measured impedance values and time values.

8. The method of claim 6, wherein determining quantile statistics for the electrical characterization data includes calculating, for each parameter value of the measured electrical responses, one or more of:
a median of the measured values associated with a same parameter value;
a quartile of the measured values associated with a same parameter value; and/or
a decile of the measured values associated with a same parameter value.

9. The method of claim 1, wherein generating the graphical user interface comprises generating a graph including one or more shaded regions or lines representative of the determined quantile statistics.

10. The method of claim 9, wherein:
determining quantile statistics for the electrical characterization data comprises determining median statistics; and
generating the graph includes generating a line representative of the determined median statistics.

11. The method of claim 9, wherein:
generating the graph includes assigning a first color to illustrate a first shaded region representative of a first quantile and assigning a second color to illustrate a second shaded region representative of a second quantile, the first color being different than the second color.

12. The method of claim 1, wherein:
electrical components of the plurality of electrical components comprise cable assemblies including one or more differential pairs of conductors; and
obtaining the electrical characterization data comprises measuring, using the test equipment, one of a selection of impedance, insertion loss, return loss, far end crosstalk, near end crosstalk, far end component contribution integrated crosstalk noise, near end component contribution integrated crosstalk noise, impedance mix-mode parameters, and/or skew of the cable assemblies.

13. The method of claim 12, wherein obtaining the electrical characterization data comprises measuring the impedance of the cable assemblies by performing time domain reflectometry by:
transmitting a differential electrical signal through a differential pair of conductors of the cable assemblies from a first side of the cable assemblies to a second side of the cable assemblies, the differential electrical signal comprising a step stimulus having a rise time equal to a data rate Nyquist frequency; and
measuring, at the first side of the cable assemblies, a reflected electrical signal as a function of time.

14. The method of claim 12, wherein obtaining the electrical characterization data comprises measuring the insertion loss of the cable assemblies by:
transmitting a differential electrical signal through a differential pair of conductors of the cable assemblies from a first side of the cable assemblies to a second side of the cable assemblies, the differential electrical signal having a frequency that is varied over time; and
measuring, at the second side of the cable assemblies, a transmitted electrical signal as a function of frequency.

15. The method of claim 12, wherein obtaining the electrical characterization data comprises measuring return loss of the cable assemblies by:
transmitting a differential electrical signal through a differential pair of conductors of the cable assemblies from a first side of the cable assemblies to a second side of the cable assemblies, the differential electrical signal having a frequency that is varied over time; and
measuring, at the first side of the cable assemblies, a reflected electrical signal as a function of frequency.

16. The method of claim 12, wherein obtaining the electrical characterization data comprises measuring far end crosstalk of the cable assemblies by:
transmitting a differential electrical signal through a first differential pair of conductors of the cable assemblies from a first side of the cable assemblies to a second side of the cable assemblies, the differential electrical signal having a frequency that is varied over time, and the first differential pair of conductors being adjacent a second differential pair of conductors; and
measuring, at the second side of the cable assemblies and from the second differential pair of conductors, a transmitted electrical signal as a function of frequency.

17. The method of claim 12, wherein obtaining the electrical characterization data comprises measuring near end cross talk of the cable assemblies by:
transmitting a differential electrical signal through a first differential pair of conductors of the cable assemblies from a first side of the cable assemblies to a second side of the cable assemblies, the differential electrical signal having a frequency that is varied over time, and the first differential pair of conductors being adjacent a second differential pair of conductors; and
measuring, at the first side of the cable assemblies and from the second differential pair of conductors, a transmitted electrical signal as a function of frequency.

18. The method of claim 12, wherein obtaining the electrical characterization data comprises measuring mix-mode parameters of the cable assemblies by:
transmitting a differential electrical signal through a differential pair of conductors of the cable assemblies from a first side of the cable assemblies to a second side of the cable assemblies, the differential electrical signal having a frequency that is varied over time; and
measuring, at the second side of the cable assemblies, a transmitted common-mode electrical signal as a function of frequency.

19. The method of claim 12, wherein obtaining the electrical characterization data comprises measuring skew by performing intra-pair skew measurements as a function of time or as a function of frequency.

20. The method of claim 1, wherein obtaining the electrical characterization data comprises selecting a subset of the electrical characterization data based on serial numbers associated with the plurality of electrical components, a date of manufacture of the plurality of electrical components, lot numbers associated with the plurality of electrical components, and/or manufacturing shifts associated with a time of manufacture of the plurality of electrical components.
